(19) United States
(12) Patent Application Publication
(10) Pub. No.: US 2026/0262508 A1
(43) Pub. Date: Sep. 3, 2026

(54) ELECTRONIC DEVICES AND METHODS OF MANUFACTURING ELECTRONIC DEVICES

(71) Applicant: Amkor Technology Singapore Holding Pte. Ltd., Valley Point (SG)

(72) Inventors: Eoin O'TOOLE, Évora, PR (US); Tobias SCHRAMM, Oullins-Pierre-Bénite (FR); Paulo CARDOSO, Baguim do Monte, PR (US)

(73) Assignee: Amkor Technology Singapore Holding Pte. Ltd., Valley Point (SG)

(21) Appl. No.: 19/067,567

(22) Filed: Feb. 28, 2025

(51) Int. Cl. H01L 23/00; H01L 21/48; H01L 21/56; H01L 23/31; H01L 23/498

(52) U.S. Cl. CPC H10W 70/05; H10W 70/095; H10W 70/65; H10W 70/685; H10W 74/014; H10W 74/016; H10W 74/114; H10W 74/121; H10W 70/09; H10W 70/60; H10W 70/6528; H10W 72/0198; H10W 90/00

(57) ABSTRACT

In one example, an electronic device includes an electronic component including an upper side, a lower side, a lateral side, and component interconnects adjacent to the upper side. An encapsulant includes an encapsulant top side, an encapsulant lower side, and an encapsulant lateral side. A substrate includes a dielectric structure including a first dielectric layer and a second dielectric layer over the first dielectric layer and comprising a lateral end interposed between the lateral side of the electronic component and the encapsulant lateral side. The substrate includes a conductive structure including a first conductive layer and a second conductive layer coupled to the first conductive layer. The second conductive layer comprises a substrate edge terminal comprising a first portion that extends to overlap the lateral end of the second dielectric layer and covers a part of the first dielectric layer. Other examples and related methods are also disclosed herein.

### CROSS-REFERENCES TO RELATED APPLICATIONS

Not applicable.

### TECHNICAL FIELD

The present disclosure relates, in general, to electronic devices, and more particularly, to semiconductor devices and methods for manufacturing semiconductor devices.

### BACKGROUND

Prior semiconductor packages and methods for forming semiconductor packages are inadequate, for example resulting in excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIG. 2 shows a partial cross-sectional view of the example electronic device of FIG. 1 connected to a next level of assembly.

FIGS. 3A, 3B, 3C, 3D, 3E, 3F, 3G, and 3H show partial cross-sectional views of an example method for manufacturing an example electronic device.

FIG. 4A shows a partial cross-sectional view of an example electronic device.

FIG. 4B shows a partial cross-sectional view of an example electronic device.

FIG. 5 shows a cross-sectional view of an example electronic device.

FIG. 6 shows a partial cross-sectional view of the example electronic device of FIG. 5 connected to a next level of assembly.

FIGS. 7A, 7B, 7C, 7D, 7E, and 7F show partial cross-sectional views of an example method for manufacturing an example electronic device.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and/or “including,” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly connected by one or more other elements. For example, if element A is coupled to element B, then element A can be directly contacting element B or indirectly connected to element B by an intervening element C. Similarly, the terms “over” or “on” may be used to describe two elements directly contacting each other or describe two elements indirectly connected by one or more other elements. As used herein, the term “coupled” can refer to an electrical coupling or a mechanical coupling.

### DESCRIPTION

The present description includes, among other features, structures and associated methods that relate to electronic devices using wafer-level packaging. More particularly, structures and methods are described to improve the manufacturability of wafer level substrates, such as redistribution layer (RDL) substrates used, for example, in fine-pitch fan-out configurations. This can be referred to as a wafer-level fan-out configuration or WLFO. In some examples, substrate edge terminals are provided that extend and terminate at the substrate lateral edge to provide a wettable flank configuration. In some examples, the substrate edge terminals further extend and overlap an edge of an encapsulant that covers an internal electronic component. The wettable flank configuration protects the underlying conductor (for example, copper (Cu)) and allows soldering to occur on this external flank area of the substrate edge terminals such that optical inspection can be made verifying a good solder fillet joint, and thus a good electrical connection.

In an example, an electronic device includes an electronic component including an upper side, a lower side opposite to the upper side, a lateral side connecting the upper side to the lower side, and component interconnects adjacent to the upper side. An encapsulant includes an encapsulant top side, an encapsulant lower side, and an encapsulant lateral side, wherein the upper side of the electronic component is exposed from the encapsulant top side and the encapsulant lateral side covers the lateral side of the electronic component. A substrate includes a dielectric structure including a first dielectric layer and a second dielectric layer over the first dielectric layer and comprising a lateral end interposed between the lateral side of the electronic component and the encapsulant lateral side; and a conductive structure including a first conductive layer coupled to the component interconnects and a second conductive layer coupled to the first conductive layer. The second conductive layer comprises a substrate edge terminal comprising a first portion that extends to overlap the lateral end of the second dielectric layer and covers a part of the first dielectric layer.

In an example, an electronic device includes an electronic component including an upper side, a lower side opposite to the upper side, a lateral side connecting the upper side to the lower side, and component interconnects adjacent to the upper side. An encapsulant includes an encapsulant top side, an encapsulant lower side, and an encapsulant lateral side. The upper side of the electronic component is exposed from the encapsulant top side; and the encapsulant lateral side covers the lateral side of the electronic component. A substrate includes a dielectric structure including a first dielectric layer and a second dielectric layer over the first dielectric layer and comprising a lateral end interposed between the lateral side of the electronic component and the encapsulant lateral side. A conductive structure includes a first conductive layer comprising substrate inward terminals coupled to the component interconnects and a second conductive layer comprising a substrate outward terminal and a substrate edge terminal coupled to the first conductive layer. The substrate edge terminal includes a first portion that extends to overlap the lateral end of the second dielectric layer and covers a part of the first dielectric layer proximate the encapsulant lateral side.

In an example, a method of manufacturing an electronic device includes providing an electronic component including an upper side, a lower side opposite to the upper side, a lateral side connecting the upper side to the lower side, and component interconnects adjacent to the upper side. The method includes providing an encapsulant including an encapsulant top side, an encapsulant lower side, and an encapsulant lateral side. The upper side of the electronic component is exposed from the encapsulant top side; and the encapsulant lateral side covers the lateral side of the electronic component. providing a substrate including a dielectric structure including a first dielectric layer and a second dielectric layer over the first dielectric layer and including a lateral end interposed between the lateral side of the electronic component and the encapsulant lateral side; and a conductive structure including a first conductive layer coupled to the component interconnects and a second conductive layer coupled to the first conductive layer. The second conductive layer includes a substrate edge terminal including a first portion that extends to overlap the lateral end of the second dielectric layer and covers a part of the first dielectric layer. The first portion defines an outward facing flank surface.

Other examples are included in the present disclosure. Such examples may be found in the figures, in the claims, or in the description of the present disclosure.

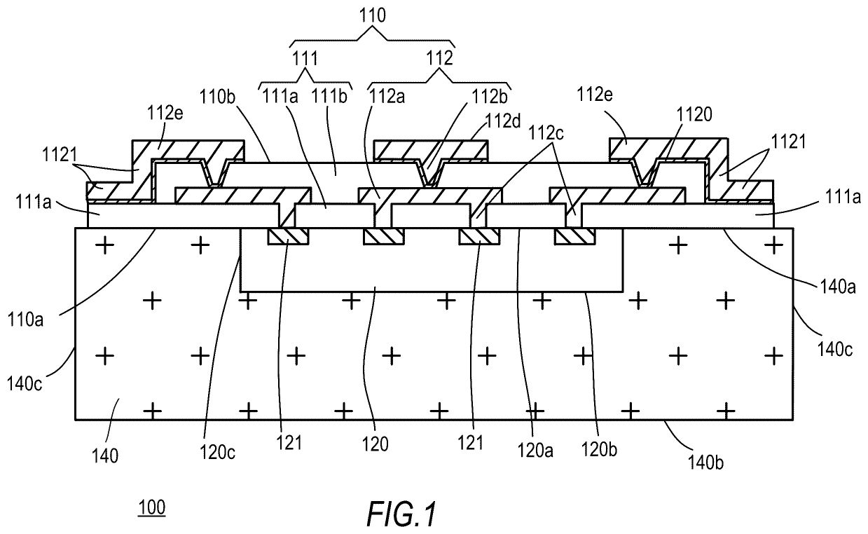

FIG. 1 illustrates a cross-sectional view of an example electronic device 100 in accordance with the present description. In the present example, electronic device 100 is shown as a WFLO structure comprising a wettable flank configuration. In the present example, electronic device 100 can comprise substrate 110, electronic component 120, and encapsulant 140.

In the present example, substrate 110 is shown as a redistribution layer (RDL) substrate. RDL substrates can comprise one or more conductive redistribution layers (for example, conductive structure 112) and one or more dielectric layers (for example, dielectric structure 111) that (a) can be formed layer by layer over an electronic component to which the RDL substrate is to be electrically coupled, or (b) can be formed layer by layer over a work piece. As is described hereinafter, RDL substrates can be manufactured layer by layer as a wafer-level substrate on a round wafer (which includes electronic component 120 and encapsulant 140) in a wafer-level process, and/or as a panel-level substrate on a rectangular or square panel carrier in a panel-level process.

RDL substrates can be formed in an additive buildup process that can include one or more dielectric layers (for example, dielectric layers 111a and 111b of dielectric structure 111) alternatingly stacked with one or more conductive layers (for example, conductive layers 112a and 112b of conductive structure 112) that define respective conductive redistribution patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise an electrically conductive material such as, for example, copper (Cu) or other plateable metals. The locations of the conductive patterns can be made using a photo-patterning process such as, for example, a photolithography process and a photoresist material to form a photolithographic mask.

The dielectric layers (for example, dielectric layers 111a and 111b) of the RDL substrate can be patterned with a photo-patterning process, which can include a photolithographic mask through which light is exposed to photo-pattern desired features such as vias in the dielectric layers. The dielectric layers can be made from photo-definable organic dielectric materials such as, for example, polyimide (PI), benzocyclobutene (BCB) based resins, or polybenzoxazole (PBO). Such dielectric materials can be attached as pre-formed films, spun-on or otherwise coated in liquid form. To permit proper formation of desired photo-defined features, such photo-definable dielectric materials can omit structural reinforcers or can be filler-free, without strands, weaves, or other particles that could interfere with the light from the photo-patterning process. In some examples, such filler-free characteristics of filler-free dielectric materials can permit a reduction of the thickness of the resulting dielectric layer.

Although the photo-definable dielectric materials described above can be organic materials, in other examples the dielectric materials of the RDL substrates can comprise one or more inorganic dielectric layers. Some examples of inorganic dielectric layer(s) can comprise silicon nitride (Si₃N₄), silicon oxide (SiO₂), and/or SiON. The inorganic dielectric layer(s) can be formed by growing the inorganic dielectric layers using an oxidation or nitridization process instead using photo-defined organic dielectric materials. Such inorganic dielectric layers can be filler-free, without strands, weaves, or other dissimilar inorganic particles. RDL substrates can also omit the permanent core structure generally associated with laminate substrates. Substrate 110 as disclosed herein, can comprise and be referred to as an RDL substrate.

In the present example, substrate 110 can comprise substrate inner side 110a, substrate outer side 110b opposite to substrate inner side 110a, dielectric structure 111, and conductive structure 112. In some examples dielectric structure 111 comprises a first dielectric layer 111a that defines substrate inner side 110a and a second dielectric layer 111b that defines substrate outer side 110b. in the some examples, dielectric layer 111a comprises a first lateral width and dielectric layer 111b comprises a second lateral width less than the first lateral width so that part of the top side of dielectric layer 111a is exposed from dielectric layer 111b proximate to the lateral edge of electronic device 100. This can form a step shape between the first dielectric layer 111a and second dielectric layer 111b in a cross-sectional view. Substrate 110 can also comprise or be referred to as fan-out RDL layers.

In some examples, conductive structure 112 can comprise conductive layer 112a and conductive layer 112b. In some examples, conductive layer 112a comprises substrate inward terminals 112c proximate to substrate inner side 110a, and conductive layer 112b comprises substrate outward terminals 112d and substrate edge terminals 112e proximate to substrate outer side 110b. In accordance with the present description, substrate edge terminals 112e are proximate to the peripheral edges of substrate 110. Substrate inward terminals 112c can also be referred to as inner contact pads, and substrate outward terminals 112d and substrate edge terminals 112e can also be referred to outer contact pads or outer lands. In some examples, conductive layer 112b includes a seed layer 1120. In some examples, conductive layer 112a can also include a seed layer similar to conductive layer 112b. In other examples, additional conductive layers can be used.

In accordance with the present description, substrate edge terminals 112e comprise portions 1121 that extend laterally outward towards the lateral edges of electronic device 100. In some examples, portions 1121 of substrate edge terminals 112e extend to overlap outer ends of dielectric layer 111b and onto portions of dielectric layer 111a. In the present example, portions 1121 comprise both vertical and horizontal parts or segments. In some examples, the segments can extend in different directions. In some examples, the directions can be substantially orthogonal to each other. In some examples, the segments can be angled with respect to each other. Portions 1121 of substrate edge terminals 112e can comprise or be referred to as wettable flank portions, wettable flank surfaces, or outward facing flank surfaces and are configured to increase the wettable area for attachment material when connecting electronic device 100 to a next level of assembly. Such attachment materials include, for example, solders. In the present example, substrate edge terminal 112e includes a segment that resides on dielectric layer 111a and is at the same interconnect level as conductive layer 112a.

In some examples, electronic component 120 comprises an upper side 120a, a lower side 120b opposite to upper side 120a, and a lateral side 120c connecting upper side 120a and lower side 120b. Upper side 120a can also be referred to as a component upper side; lower side 120b can also be referred to as a component lower side, and lateral side 120c can be referred to as a component lateral side. In the present example, lateral side 120c can define a perimeter or footprint for electronic component 120.

In the present example, electronic component 120 includes component interconnects 121 adjacent to upper side 120a and coupled to conductive structure 112. In some examples, component interconnects 121 are coupled to substrate inward terminals 112c of conductive layer 112a. Upper side 120a can comprise or be referred to as a first side or an active side of electronic component 120, and lower side 120b can comprise or be referred to as a second side or an inactive side of electronic component 120. In other examples, lower side 120b can be active side of electronic component and can be coupled to conductive structure 112 using clips or other conductive connective structures.

In some examples, encapsulant 140 encapsulates or covers lower side 120b and lateral sides 120c of electronic component 120. Encapsulant 140 comprise a top side 140a, a lower side 140b opposite to top side 140a, and a lateral side 140c connecting top side 140a to lower side 140b. Top side 140a can be referred to as an encapsulant top side; lower side 140b can be referred to as an encapsulant lower side; and lateral side 140c can be referred to as an encapsulant lateral side.

In the present example, upper side 120a of electronic component 120 is exposed from encapsulant 140 at top side 140a. In the present example, upper side 120a is covered by substrate 110 including dielectric structure 111 and conductive structure 112. In the present example, conductive layer 112b includes substrate edge terminals 112e that laterally extend to a location proximate to lateral side 140c of encapsulant 140. In the present example, lateral side 140c and an end portion of dielectric layer 111a are devoid of conductive layer 112b. As will be described later, substate edge terminal can extend to overlap the end portion of dielectric layer 111a and can extend on to exposed portions of top side 140a of encapsulant 140.

Substrate 110 and encapsulant 140 can be referred to as an electronic package or package. The electronic package can protect electronic component 120 from exposure to external elements and/or environments. The electronic package can also provide electrical coupling between electronic component 120 and an external component or other electronic packages.

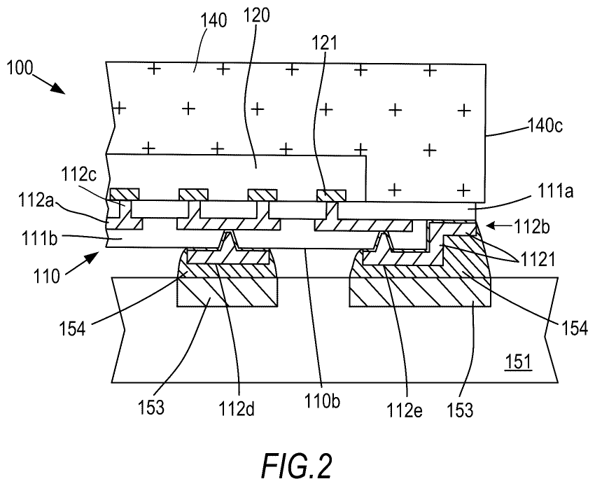

FIG. 2 illustrates a partial cross-sectional view of electronic device 100 connected to a next level of assembly, such as an assembly board 151. In the present example, assembly board 151 comprises a printed circuit board (PCB) or mounting substrate. In some examples, assembly board 151 includes conductive traces 153 proximate to the top side of assembly board 151. In the present example, substrate outward terminal 112d and substrate edge terminal 112e of conductive layer 112b are attached to conductive traces 153 with an attachment material 154, such as a solder. In accordance with the present description, portions 1121 of substrate edge terminal 112e provide additional surface area for attachment material 154 compared to previous devices. Among other things, this enhances the ability to perform any necessary visual inspections of the bonded surfaces.

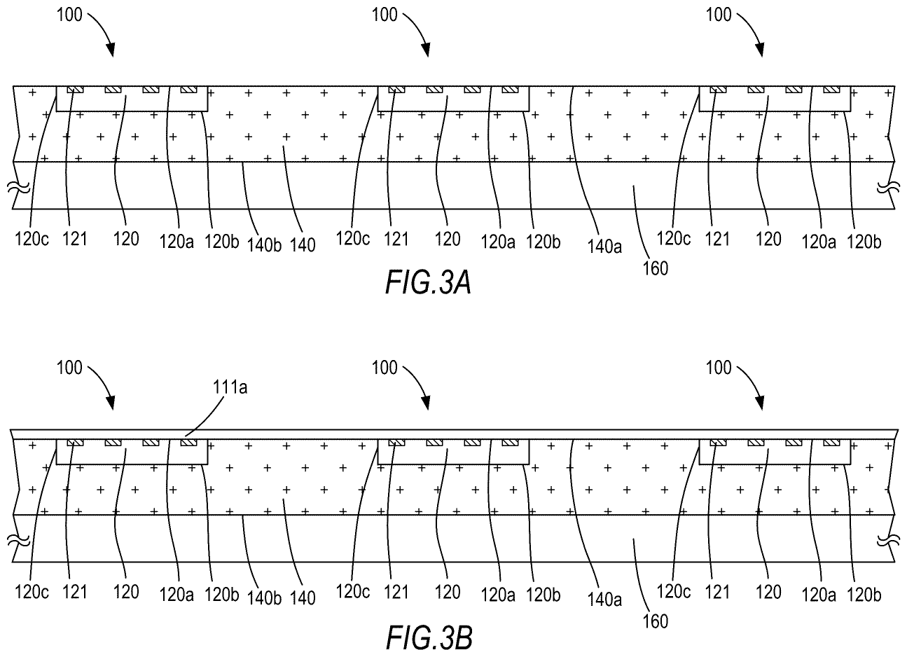

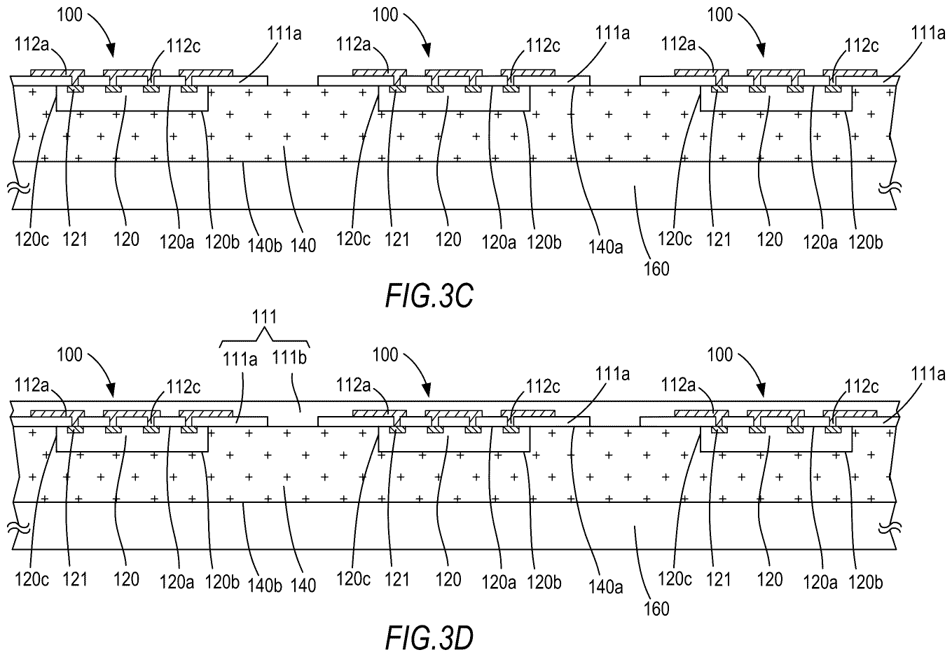

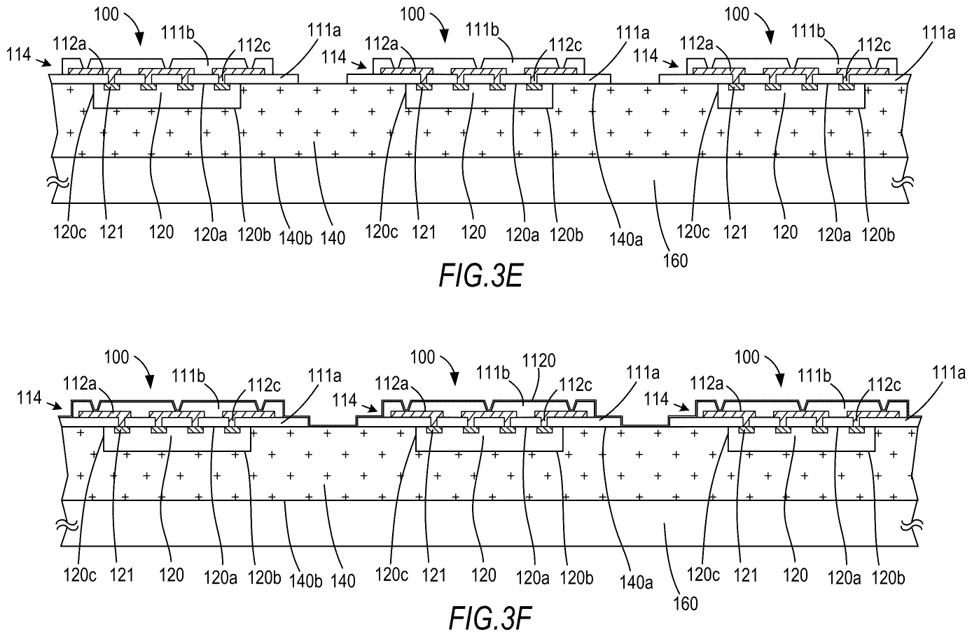

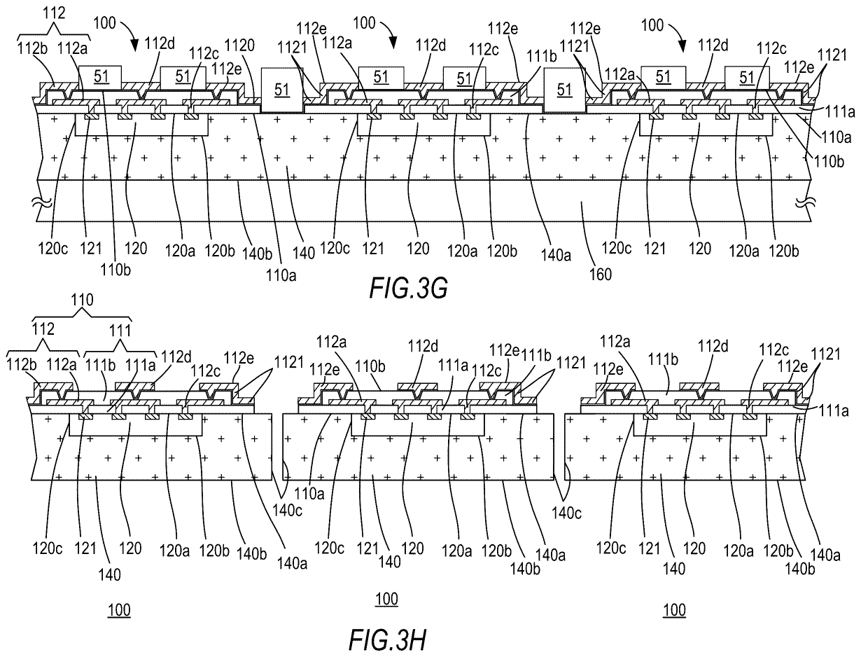

FIGS. 3A to 3H show cross-sectional views of an example method for manufacturing an example electronic device, such as electronic device 100 illustrated in FIG. 1.

FIG. 3A is a cross-sectional view of electronic device 100 at an early stage of manufacture. In the example shown in FIG. 3A, electronic device 100 is shown as a plurality of electronic devices 100 comprising electronic components 120 and encapsulant 140 coupled to a carrier 160.

In the present example, electronic components 120 are provided covered by encapsulant 140 with upper sides 120a of the electronic components 120 exposed from top side 140a of encapsulant 140. In some examples, carrier 160 can be provided as a round wafer in a wafer-level process, or as a panel-level substrate on a rectangular or square panel carrier in a panel-level process. In some examples, carrier 160 can comprise silicon, glass, ceramic, or other materials as known to one of ordinary skill in the art. In some examples, carrier 160 has a thickness in a range from approximately 3 microns through 300 microns.

In some examples, electronic components 120 can each comprise or be referred to as a semiconductor die, a semiconductor chip, or a semiconductor package. The semiconductor die or chip can comprise an integrated circuit die separated from a semiconductor wafer. Electronic components 120 can comprise digital signal processors (DSPs), network processors, power management units, audio processors, RF circuits, wireless baseband system on a chip (SoC) processors, sensors, memory, and application specific integrated circuits (ASIC). In other examples, electronic components 120 can comprise power semiconductor devices, such as metal-oxide-semiconductor field-effect transistor (MOSFET) or bipolar transistor devices. Electronic components 120 can comprise active or passive components. Electronic components 120 can have a thickness of about 20 μm to about 1000 μm. In some examples, electronic components 120 can perform calculations and control processing, store data, or remove noise from electrical signals.

In some examples, electronic components 120 can comprise component interconnects 121 adjacent to upper sides 120a. In some examples, the component connects can be on or overlying upper sides 120a. Component interconnects 121 a can comprise or be referred to as terminals, bond pads, bumps, pillars, pads, or solder balls. Component interconnects 121 can be provided as electrical contacts between electronic components 120 and substrate 110. In some examples, component interconnects 121 can comprise copper (Cu), lead (Pb), tin (Sn), aluminum (Al), palladium (Pd), titanium (Ti), tungsten (W), titanium/tungsten (Ti/W), nickel (Ni), gold (Au), silver (Ag), or tin/silver (SnAg)

In some examples, encapsulant 140 can comprise epoxy resin or phenolic resin, carbon black, silica filler, or other materials known to one of ordinary skill in the art. In some examples, encapsulant 140 can comprise or be referred to as a body, a molding, a mold compound, a resin, a sealant, a filler-reinforced polymer, or an organic body.

In some examples, encapsulant 140 can be on lateral sides 120c and lower sides 120b of electronic components 120. In some examples, upper sides 120a of electronic components 120 can be exposed from top side 140a of encapsulant 140 to the outside of encapsulant 140. In some examples, upper sides 120a and top side 140a can be substantially coplanar. In some examples, a portion of encapsulant 140 is between lateral sides 120c of electronic components 120 that laterally face each other. In other examples, lower sides 120b of electronic components 120 can be exposed from encapsulant 140 at lower side 140b.

In some examples, encapsulant 140 can be provided by compression molding, transfer molding, liquid phase molding, vacuum lamination, paste printing, or film assist molding. Compression molding can be a process where a flowable resin is supplied into a mold in advance, and an electronic component is then put into the mold to cure the flowable resin, and transfer molding can be a process where a flowable resin is supplied from a gate (supply port) of a mold to the periphery of an electronic component and then cured. Encapsulant 140 can have a thickness of about 100 μm to about 1000 μm. Encapsulant 140 can protect electronic components 120 from external elements or environmental exposure.

FIG. 3B shows electronic devices 100 after additional processing. In the present example, the fabrication of substrate 110 can start as a build-up process by providing dielectric layer 111a over upper sides 120a of electronic components 120 and top side 140a of encapsulant 140. In some examples, dielectric layer 111a can comprise photo-definable organic dielectric materials such as, polyimide (PI), benzocyclobutene (BCB) based resins, or polybenzoxazole (PBO). To permit proper formation of desired photo-defined features, such photo-definable dielectric materials can omit structural reinforcers or can be filler-free, without strands, weaves, or other particles that could interfere with the light from the photo-patterning process. In some examples, such filler-free characteristics of filler-free dielectric materials can permit a reduction of the thickness of the resulting dielectric layer. In some examples, when dielectric layer 111a comprises an organic dielectric material, dielectric layer 111a can be provided by attaching pre-formed films, spin coating, spray coating, printing, or other techniques as known to one of ordinary skill in the art. In some examples, layer 111a comprises an inorganic dielectric, such as silicon nitride (Si₃N₄), silicon oxide (SiO₂), and/or SiON. Such inorganic dielectrics can be filler-free, without strands, weaves, or other dissimilar inorganic particles. In some examples, when dielectric layer 111a comprises an inorganic dielectric, dielectric layer 111a can be provided by attaching pre-formed films, spin coating, spray coating, printing, oxidation, physical vapor deposition (PVD), chemical vapor deposition (CVD), metal organic chemical vapor deposition (MOCVD), atomic layer deposition (ALD), low pressure chemical vapor deposition (LPCVD), plasma enhanced chemical vapor deposition (PECVD), or other processes as known to one of ordinary skill in the art. In some examples, thickness of dielectric layer 111a can range from about 1 micron to about 10 microns.

FIG. 3C shows electronic devices 100 after additional processing. In the present example, dielectric layer 111a is patterned to provide openings to expose portions of component interconnects 121 and portions of encapsulant 140 between electronic components 120. In some examples, photolithography and etch processes are used to pattern dielectric layer 111a. A conductive material can then be provided over dielectric layer 111a and encapsulant 140 and patterned to provide conductive layer 112a over dielectric layer 111a and substrate inward terminals 112c coupled to component interconnects 121.

Conductive layer 112a can comprise and be referred to as a conductive pattern and is an example of a first conductive pattern. In some examples, conductive layer 112a can comprise Cu, Al, Pd, Ti, W, TiW, Ni, Au, Ag, or SnAg, and can be provided by sputtering, electroless plating, electrolytic plating, PVD, CVD, MOCVD, ALD, LPCVD, PECVD, or other processes as known to one of ordinary skill in the art. The locations of conductive layer 112a over dielectric layer 111a can be made using a photo-patterning process such as, for example, a photolithography process and a photoresist material to form a photolithographic mask followed by an etching process.

In some examples, conductive layer 112a can comprise or be referred to as one or more conductors, conductive materials, a conductive path, a conductive pattern, a redistribution layer (RDL), a wiring layer, traces, vias, lands, pads, or under bump metallization (UBM). In some examples, substrate inward terminals 112c can also be referred to as pads, lands, UBMs, or studs. Conductive layer 112a can be an example of a first conductive pattern. In some examples, the thickness of conductive layer 112a can range from 1 micron to about 40 microns. In other examples, the thickness of conductive layer 112a can range from about 1 micron to about 10 microns.

FIG. 3D shows electronic devices 100 after additional processing. In the present example, dielectric layer 111b is provided over conductive layer 112a, dielectric layer 111a, and encapsulant 140. In some examples, dielectric layer 111b can comprise similar materials, can be provided using similar processes, and can comprise similar thicknesses to dielectric layer 111a. In other examples, dielectric layer 111b can comprise a different material, can be provided using a different process, or can comprise a different thickness than dielectric layer 111a. In the present example, dielectric layer 111a and dielectric layer 111b form dielectric structure 111. It is understood that in some examples, additional dielectric layers can be used. The combined thickness of all layers of dielectric structure 111 can define the thickness of substrate 110. In some examples, the total thickness of dielectric structure 111 can range from about 10 microns to about 1000 microns.

FIG. 3E shows electronic devices 100 after additional processing. In the present example, dielectric layer 111b is patterned to provide openings to expose portions of conductive layer 112a, portions of dielectric layer 111a, and portions of encapsulant 140 between electronic components 120. Photolithography and etch processes can be used to pattern dielectric layer 111b. In the present example, dielectric layer 111b is provided laterally in-set with respect to dielectric layer 111a to provide step portions 114. Stated differently, in each of electronic devices 100, the lateral width of dielectric layer 111b is less than the lateral width of dielectric layer 111a.

FIG. 3F shows electronic devices 100 after additional processing, In the present example, seed layer 1120 is provided over dielectric layer 111b, portions of conductive layer 112a, portions of dielectric layer 111a, and potions of encapsulant 140. In some examples, seed layer 1120 comprises a conductive material, such as titanium copper (TiCu). In some examples, the titanium layer can have a thickness in a range from about 50 nanometers (nm) to 100 nm, and the copper layer can have a thickness in a range from about 150 nm to about 250 nm. In examples, where electronic component 120 comprises a power device, the thickness of the copper layer can be thicker than 250 nm. In some examples, seed layer 1120 can be formed by electroless plating, electrolytic plating, sputtering, PVD, CVD, MOCVD, ALD, LPCVD, PECVD, or other processes as known to one of ordinary skill in the art.

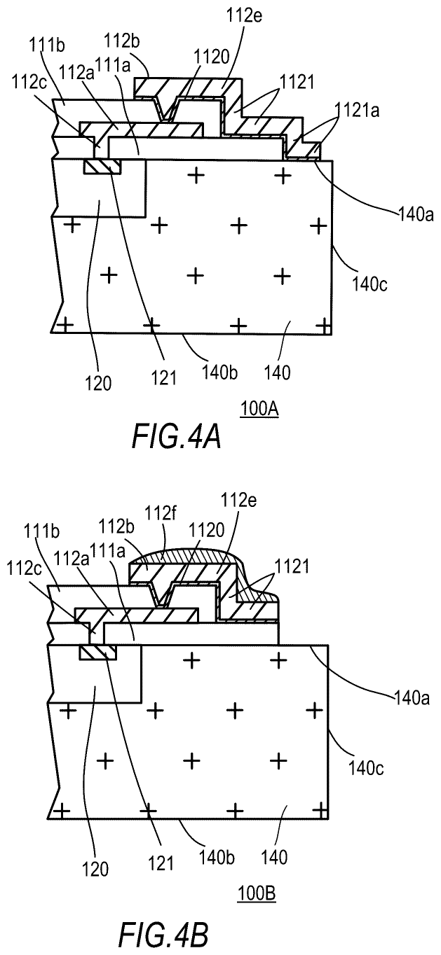

FIG. 3G shows electronic devices 100 after additional processing. In the present example, a mask 51 is provided over portions of seed layer 1120. In some examples, a masking layer is provided and then patterned to provide openings to expose portions of seed layer 1120 where conductive layer 112b will be provided. In some examples, mask 51 comprises a dry resist provided using a photolithography process and can have a thickness in a range from about 20 microns to about 50 microns. Conductive layer 112b with substrate outward terminals 112d is then provided within the openings of mask 51. In some examples, conductive layer 112b is provided using a plating process. In some examples, conductive layer 112b comprises CuNiAu and can have thickness in a range from about 5 microns to about 25 microns. In some examples, the thickness can be in a range from about 5 microns to about 15 microns. In other examples, conductive layer 112b can further comprise a solder layer (see for example, solder layer 112f in FIG. 4B), such as SnAg provided using a plating process or SnAgCu (SAC) provided using a ball drop process.

Conductive layer 112b can comprise or be referred to as a conductor, a conductive material, a conductive path, a conductive pattern, an RDL, a wiring layer, traces, vias, lands, pads, or under bump metallization (UBM). In some examples, substrate outward terminals 112d and substrate edge terminals 112e can be referred to as two-step pads, pads, or lands. Conductive layer 112b is an example of a second conductive pattern.

In the present example, conductive layer 112b includes substrate outward terminals 112d and substrate edge terminals 112e. In accordance with the present description, substrate edge terminals 112e comprise portions 1121 that extend laterally outward towards the lateral edges of electronic device 100. In some examples, portions 1121 extend to overlap outer ends of dielectric layer 111b and onto portions of dielectric layer 111a. In the present example, portions 1121 comprise both vertical and horizontal parts or segments. In some examples, the segments can extend in different directions. In some examples, the directions can be substantially orthogonal to each other. In the present example, portions 1121 of substrate edge terminals 112e are interposed between lateral sides 120c of electronic components and lateral sides 140c of encapsulant 140. Stated another way, portions 1121 are external to the footprint or perimeter of electronic components 120. In some examples, the segments can be angled with respect to each other. Portions 1121 can comprise or be referred to as wettable flank portions, wettable flank surfaces, or outward facing flank surfaces and are configured to increase the wettable area for attachment material when connecting electronic device 100 to a next level of assembly. Such attachment materials include, for example, solders. Portions 1121 are an example of first wettable flank portions or first outward facing flank surfaces.

In the present example, substrate 110 comprises dielectric structure 111, which includes dielectric layers 111a and 111b, and conductive structure 112, which includes conductive layers 112a and 112b, substrate inward terminals 112c, substrate outward terminals 112d, and substrate edge terminals 112e with portions 1121. Substrate 110 comprising dielectric structure 111 and conductive structure 112 can support electronic component 120 and can couple electronic component 120 and an external device to each other. It is understood that additional dielectric layers or conductive layers can be used with substrate 110. In some examples, the traces or vias couple substrate outward terminals 112d and substrate edge terminals 112e to substrate inward terminals 112c. In some examples, substrate outward terminals 112d and substrate edge terminals 112e can protrude outward from dielectric layer 111b.

In the present example, substrate 110 comprises substrate inner side 110a adjacent to top side 140a of encapsulant 140 and upper side 120a of electronic component 120, and substrate outer side 110b opposite to substrate inner side 110a.

In some examples, after conductive layer 112b is provided, mask 51 can be removed and those portions of seed layer 1120 that were covered by mask 51 can removed, using, for example, etch processing. In some examples, conductive layer 112b can act as a mask during the removal of the exposed portions of seed layer 1120. In subsequent steps, a singulation process can be used to separate the structure into individual electronic devices 100 as shown in FIG. 3H. In some examples, laser singulation or sawing singulation can be used to separate the structure through encapsulant 140. In some examples, the singulation process defines lateral sides 140c of encapsulant 140. In the present example, lateral sides 140c of encapsulant 140 comprise singulated surfaces and are other than molded surfaces. In some examples, carrier 160 can be removed after the singulation process. In other examples, carrier 160 can be removed before the singulation process.

FIG. 4A illustrates a partial cross-sectional view of an example electronic device 100A in accordance with the present description. Electronic device 100A has similarities to electronic device 100 and such similarities will not be repeated here. In the present example, substrate edge terminals 112e further includes portion 1121a of conductive layer 112b that laterally extend further toward lateral side 140c of encapsulant 140. In the present examples, portion 1121a covers an end surface of dielectric layer 111a and extends onto and contacts top side 140a of encapsulant 140. In accordance with the present description, portion 1121a provide additional surface area for attachment materials when electronic device 100A is attached to a next level of assembly. Among other things, this this enhances the ability to perform any necessary visual inspections of the bonded surfaces.

FIG. 4B illustrates a partial cross-sectional view of an example electronic device 100B in accordance with the present description. Electronic device 100B has similarities to electronic device 100 and such similarities will not be repeated here. In the present example, conductive layer 112b further comprises a solder layer 112f formed over the top side of conductive layer 112b. In some examples, solder layer 112f can comprise SnAg provided using a plating process or SnAgCu (SAC) provided using a ball drop process. In some examples, solder layer 112f can be provided as semi ball structures. Solder layer 112f is illustrated in FIG. 4B after a reflow process. Solder layer 112f can comprise or be referred to as a solder or a solder structure. It is understood that other solder materials can be used and that solder layer 112f can be used with any of the examples described herein.

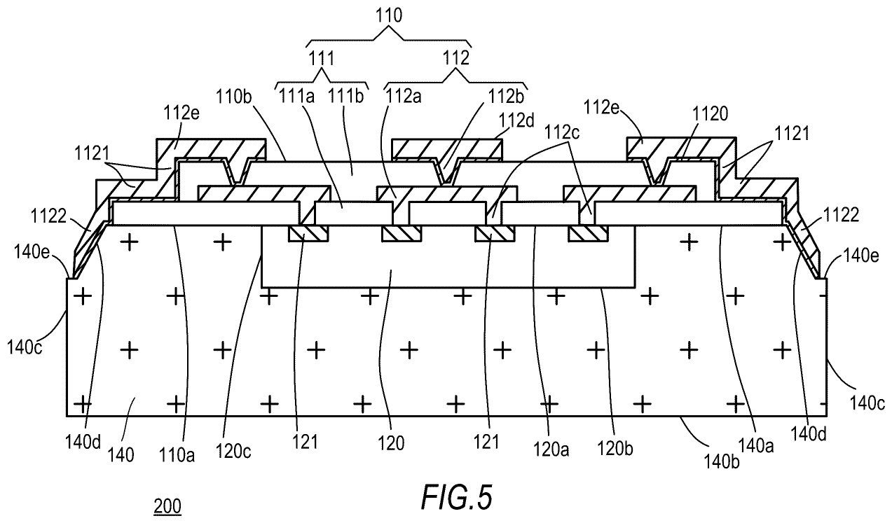

FIG. 5 illustrates a cross-sectional view of an example electronic device 200 in accordance with the present description. In the present example, electronic device 200 is shown as a WFLO structure comprising a wettable flank configuration. In the present example, electronic device 200 can comprise substrate 110, electronic component 120, and encapsulant 140. Electronic device 200 has some similarity in construction to electronic device 100 and such similarity will not be repeated here. In this regard, only certain distinctions between the electronic devices will be described.

In accordance with the present description, encapsulant 140 in electronic device 200 comprises a tapered edge 140d that can extend from top side 140a to lateral side 140c of encapsulant 140. Tapered edge 140d can comprise and be referred to as a recess, a recessed sidewall, sloped sidewall, or a groove. In addition, in electronic device 200, substrate edge terminals 112e further comprise portions 1122 that laterally extend to cover lateral edge of dielectric layer 111a, top side 140a, and tapered edge 140d of encapsulant 140. In the present example, substrate edge terminals 112e terminate on encapsulant 140 at a location that is below top side 140a of encapsulant 140. In other examples, the edges provided extending into encapsulant 140 can be less tapered than shown in FIG. 5 or can be substantially vertical.

In some examples, encapsulant 140 comprises a ledge 140e adjacent to the lower extent of tapered edge 140d that is devoid of substrate edge terminal 112e. This avoids singulating through substrate edge terminals 112e when electronic devices 200 are separated into individual devices. In other examples, substrate edge terminal 112e can cover ledge 140e. Similar to portions 1121, portions 1122 can comprise or be referred to as wettable flank portions or outward facing flank surfaces and are configured to increase the wettable area for attachment material when connecting electronic device 200 to a next level of assembly. Such attachment materials include, for example, solders.

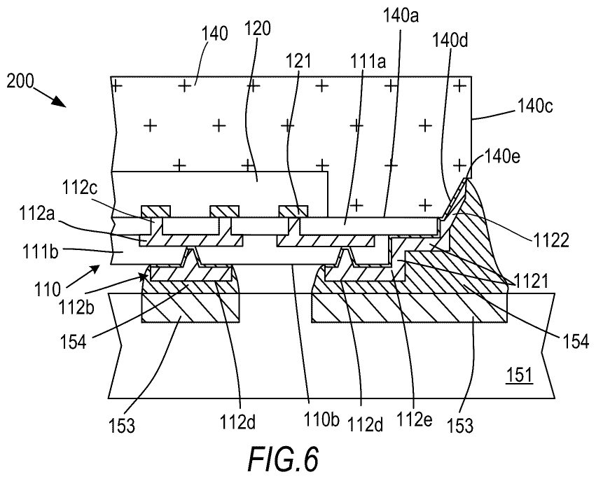

FIG. 6 illustrates a partial cross-sectional view of electronic device 200 connected to an assembly board 151. In the present example, substrate outward terminal 112d and substrate edge terminals 112e are attached to conductive traces 153 with attachment material 154. In accordance with the present description, portions 1121 and portions 1122 of substrate edge terminal 112e provide additional surface area for attachment material 154 compared to previous devices. Among other things, this enhances the ability to perform any necessary visual inspections of the bonded surfaces. In some examples, attachment material 154 can overlap or contact ledge 140e.

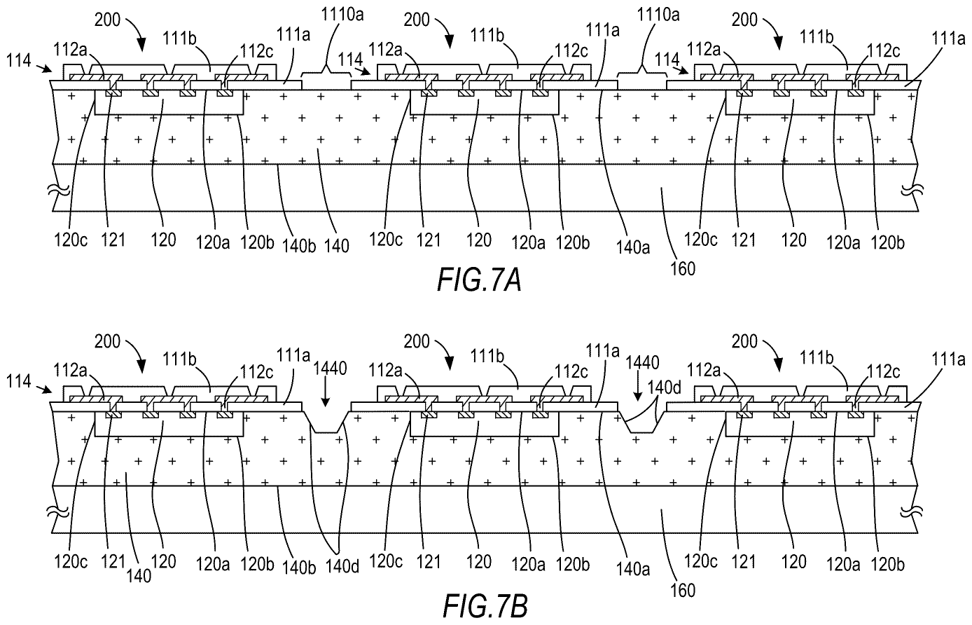

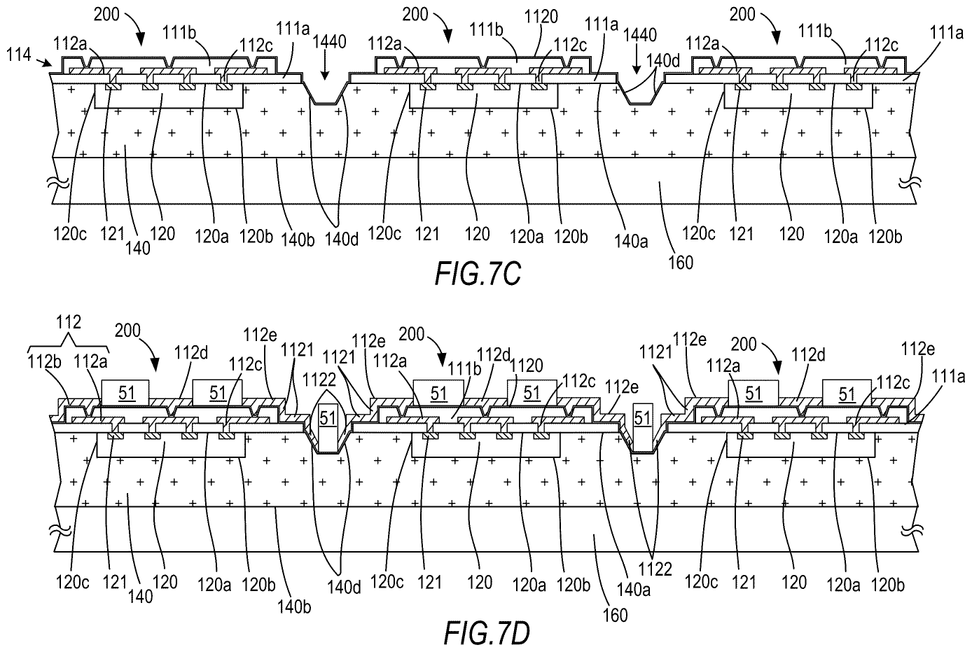

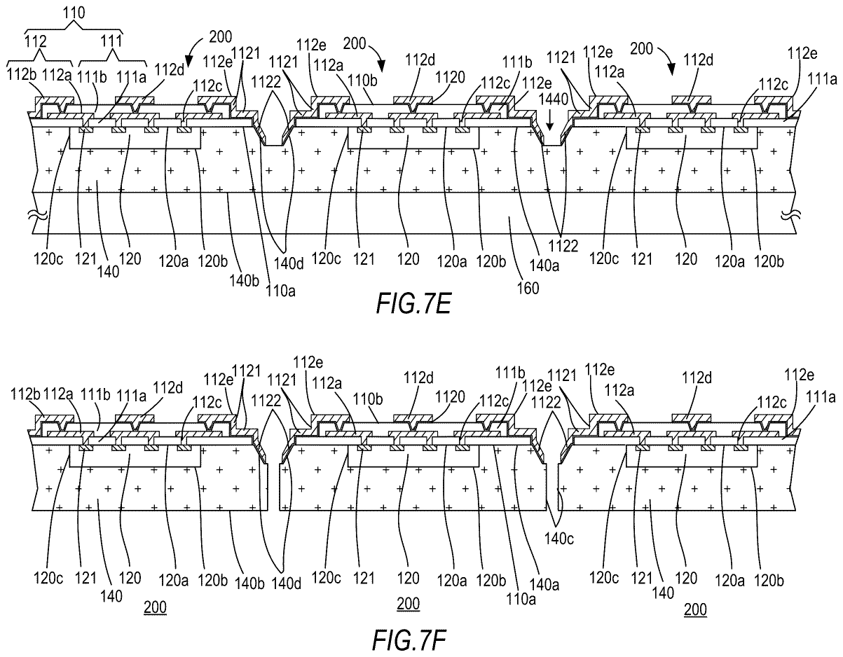

FIGS. 7A to 7F show cross-sectional views of an example method for manufacturing an example electronic device, such as electronic device 200 illustrated in FIG. 5. The method described in FIGS. 7A to 7F has some similarity to the method described in FIGS. 3A to 3H and such similarity will not be repeated here. In this regard, only certain distinctions between the methods will be described.

FIG. 7A is a cross-sectional view of electronic device 200 at a stage of manufacture. In the example shown in FIG. 7A, electronic device 200 is shown as a plurality of electronic components 120 and encapsulant 140 coupled to carrier 160. In the present example, portions of substrate 110 have been provided over top side 140a of encapsulant 140 and upper side 120a of electronic components 120 as described previously, for example with FIGS. 3A to 3E before seed layer 1120 and conductive layer 112b are provided. As shown in FIG. 7A, openings 1110a have been provided in dielectric layer 111a to expose portions of top side 140a of encapsulant 140, which can correspondence to singulation lines or scribe grids for separating electronic devices 200 into individual devices. In other examples, dielectric layer 111a can comprise a reduced thickness in the singulation lines.

FIG. 7B shows electronic devices 200 after additional processing, In the present example, grooves 1440 are formed within openings 1110a and partially extending inward from top side 140a into encapsulant 140. This provides tapered edges 140d in encapsulant 140. In some examples, a dicing blade having tapered edges can be used to form grooves 1440 in encapsulant 140. In other examples, laser scribing or etching can be used to form grooves 1440. In some examples, grooves 1440 extend to a depth in a range from about 25 microns to about 250 microns or more into encapsulant 140. In some examples, grooves 1440 extend to a depth that is below lower sides 120b of electronic components 120. In other examples, grooves 1440 extend to depth that is between upper sides 120a and lower sides 120b of electronic components 120. After grooves 1440 are formed, the surfaces of grooves 1440 can be cleaned and prepared for further processing.

FIG. 7C shows electronic devices 200 after additional processing. In the present example, seed layer 1120 is provided over dielectric layer 111b, portions of conductive layer 112a, portions of dielectric layer 111a, and grooves 1440. In some examples, seed layer 1120 comprises a conductive material, such as titanium copper (TiCu). In some examples, the titanium layer can have a thickness in a range from about 50 nanometers (nm) to 100 nm, and the copper layer can have a thickness in a range from about 150 nm to about 250 nm. In examples, where electronic component 120 comprises a power device, the thickness of the copper layer can be thicker than 250 nm. In some examples, seed layer 1120 can be formed by electroless plating, electrolytic plating, sputtering, PVD, CVD, MOCVD, ALD, LPCVD, PECVD, or other processes known to one of ordinary skill in the art. Tapered edges 140d provide for improved step coverage of seed layer 1120 within grooves 1440, which improves the coverage of portions 1122 of conductive layer 112b.

FIG. 7D shows electronic devices 200 after additional processing. n the present example, mask 51 is provided over portions of seed layer 1120. In some examples, a masking layer is provided and then patterned to provide openings to expose portions of seed layer 1120 where conductive layer 112b will be provided. In some examples, mask 51 comprises a dry resist provided using a photolithography process and can have a thickness in a range from about 20 microns to about 50 microns. Conductive layer 112b with substrate outward terminals 112d and substrate edge terminals 112e is then provided within the openings of mask 51. In some examples, conductive layer 112b is provided using a plating process. In some examples, conductive layer 112b comprises CuNiAu and can have thickness in a range from about 5 microns to about 25 microns. In other examples, conductive layer 112b can further comprise a solder layer (see for example, solder layer 112f in FIG. 4B), such as SnAg provided using a plating process or SnAgCu (SAC) provided using a ball drop process.

In accordance with the present description, substrate edge terminals 112e include portions 1122 that extend laterally outward from portions 1121 and overlap onto tapered edges 140d of encapsulant 140. In the present example, portions 1122 are interposed between lateral sides 120c of electronic components and lateral sides 140c of encapsulant 140. Stated another way, portions 1122 are external to the footprint or perimeter of electronic components 120. Portions 1122 can comprise or be referred to as wettable flank portions, wettable flank surfaces, or outward facing flank surfaces and are configured to increase the wettable area for attachment material when connecting electronic device 200 to a next level of assembly. Such attachment materials include, for example, solders. Portions 1122 are an example of second wettable flank portions or second outward facing flank surfaces.

FIG. 7E shows electronic devices 200 after additional processing. In the present example, after conductive layer 112b is provided, mask 51 can be removed and those portions of seed layer 1120 that were covered by mask 51 can removed, using, for example, etch processing. In some examples, conductive layer 112b can act as a mask during the removal of the expose portions of seed layer 1120.

In the present example, substrate 110 comprises dielectric structure 111, which includes dielectric layers 111a and 111b, and conductive structure 112, which includes conductive layers 112a and 112b, substrate inward terminals 112c, substrate outward terminals 112d, and substrate edge terminals 112e with portions 1121. It is understood that additional dielectric layers or conductive layers can be used with substrate 110. In some examples, the traces or vias couple substrate outward terminals 112d and substrate edge terminals 112e to substrate inward terminals 112c.

FIG. 7F shows electronic devices 200 after additional processing. In the present example, a singulation process can be used to separate the structure into individual electronic devices 200. In some examples, laser singulation or sawing singulation can be used to separate the structure through encapsulant 140. In some examples, the singulation process defines lateral sides 140c of encapsulant 140. In some examples, carrier 160 can be removed after the singulation process. In other examples, carrier 160 can be removed before the singulation process.

In another example, grooves 1440 can be extended to a depth below lower sides 120b of electronic components 120 and a removal step is used to remove a portion of encapsulant 140 from lower side 140b until the removal process reaches the lower side of grooves 1440. In other examples, a partial singulation can be done through the lower side of grooves 1440 and the removal process can be done and terminated onside the lower side of the partial singulation is reached. Back grinding or etching can be used for the removal process.

In other examples, substrate 110 for electronic device 100 or electronic device 200 can comprise a pre-formed substrate. The pre-formed substrate can be manufactured prior to attachment to an electronic device and can comprise dielectric layers between respective conductive layers. The conductive layers can comprise copper and can be formed using an electroplating process. The dielectric layers can be relatively thicker non-photo-definable layers and can be attached as a pre-formed film rather than as a liquid and can include a resin with fillers such as strands, weaves, or other inorganic particles for rigidity or structural support. Since the dielectric layers are non-photo-definable, features such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a dielectric material comprising bismaleimide triazine (BT) or FR4, and dielectric and conductive layers can be formed on the permanent core structure. In other examples, the pre-formed substrate can be a coreless substrate omitting the permanent core structure, and the dielectric and conductive layers can be formed on a sacrificial carrier and is removed after formation of the dielectric and conductive layers and before attachment to the electronic device. The pre-formed substrate can be referred to as a printed circuit board (PCB) or a laminate substrate. Such pre-formed substrate can be formed through a semi-additive or modified-semi-additive process. In additional examples, substrate 110 can comprise a multi-layer substrate or a molded lead frame.

In summary, structures and associated methods have been described that relate to electronic devices having improved wettable flank capability. More particularly, structures and methods have been described that improve the manufacturability of wafer level substrates, such as redistribution layer (RDL) substrates with substrate edge terminals that extend and terminate at the substrate lateral edge to provide a wettable flank configuration. In some examples, the substrate edge terminals further extend and overlap an edge of an encapsulant that covers an internal electronic component. The wettable flank configuration protects the underlying conductor (for example, copper (Cu)) and allows soldering to occur on this external flank area of the substrate edge terminals such that optical inspection can be made verifying a good solder fillet joint, and thus a good electrical connection.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device, comprising:
an electronic component comprising:
an upper side;
a lower side opposite to the upper side;
a lateral side connecting the upper side to the lower side; and
component interconnects adjacent to the upper side;
an encapsulant comprising:
an encapsulant top side;
an encapsulant lower side; and
an encapsulant lateral side, wherein:
the upper side of the electronic component is exposed from the encapsulant top side; and
the encapsulant lateral side covers the lateral side of the electronic component; and
a substrate comprising:
a dielectric structure comprising:
a first dielectric layer; and
a second dielectric layer over the first dielectric layer and comprising a lateral end interposed between the lateral side of the electronic component and the encapsulant lateral side; and
a conductive structure comprising:
a first conductive layer coupled to the component interconnects; and
a second conductive layer coupled to the first conductive layer;
wherein:
the second conductive layer comprises a substrate edge terminal comprising a first portion that extends to overlap the lateral end of the second dielectric layer and covers a part of the first dielectric layer.

2. The electronic device of claim 1, wherein:
the first dielectric layer comprises a first lateral width;
the second dielectric layer comprises a second lateral width less than the first lateral width; and
the first portion of the substrate edge terminal contacts a top side of the first dielectric layer proximate to the encapsulant lateral side.

3. The electronic device of claim 1, wherein:
the encapsulant comprises a tapered edge that extends from the encapsulant top side to the encapsulant lateral side; and
the substrate edge terminal comprises a second portion that extends to cover a portion of the tapered edge.

4. The electronic device of claim 3, wherein:
the second portion of the substrate edge terminal terminates a location on the tapered edge that is between the upper side of the electronic component and the lower side of the electronic component.

5. The electronic device of claim 1, wherein:
the first portion of the substrate edge terminal comprises segments that extend in different directions that define a wettable flank surface.

6. The electronic device of claim 1, wherein:
the first portion of the substrate edge terminal contacts the encapsulant top side.

7. The electronic device of claim 1, wherein:
the substrate edge terminal overlaps a top side of the second dielectric layer and protrudes outward from the top side of the second dielectric layer.

8. The electronic device of claim 1, further in combination with:
an assembly board comprising a conductive trace;
wherein:
the substrate edge terminal is coupled to the conductive trace with an attachment material; and
the attachment material covers the first portion of the substrate edge terminal.

9. The electronic device of claim 1, wherein:
the encapsulant lateral side comprises a singulated surface.

10. The electronic device of claim 1, wherein:
the substrate comprises a redistribution layer (RDL) substrate; and
the second conductive layer comprises a seed layer and a plated material.

11. An electronic device, comprising:
an electronic component comprising:
an upper side;
a lower side opposite to the upper side;
a lateral side connecting the upper side to the lower side; and
component interconnects adjacent to the upper side;
an encapsulant comprising:
an encapsulant top side;
an encapsulant lower side; and
an encapsulant lateral side, wherein:
the upper side of the electronic component is exposed from the encapsulant top side; and
the encapsulant lateral side covers the lateral side of the electronic component; and
a substrate comprising:
a dielectric structure comprising:
a first dielectric layer; and
a second dielectric layer over the first dielectric layer and comprising a lateral end interposed between the lateral side of the electronic component and the encapsulant lateral side; and
a conductive structure comprising:
a first conductive layer comprising substrate inward terminals coupled to the component interconnects; and
a second conductive layer comprising a substrate outward terminal and a substrate edge terminal coupled to the first conductive layer;
wherein:
the substrate edge terminal comprises a first portion that extends to overlap the lateral end of the second dielectric layer and covers a part of the first dielectric layer proximate the encapsulant lateral side.

12. The electronic device of claim 11, wherein:
the encapsulant comprises a tapered edge that extends from the encapsulant top side to the encapsulant lateral side; and
the substrate edge terminal comprises a second portion that extends to cover a portion of the tapered edge.

13. The electronic device of claim 12, wherein:
the second portion of the substrate edge terminal terminates a location on the tapered edge that is between the upper side of the electronic component and the lower side of the electronic component.

14. The electronic device of claim 13, wherein:
the encapsulant lateral side comprises a ledge adjacent to a lower extend of the tapered edge; and
the ledge is devoid of the second portion of the substrate edge terminal.

15. The electronic device of claim 14, further in combination with:
an assembly board comprising a conductive trace;
wherein:
the substrate edge terminal is coupled to the conductive trace with an attachment material; and
the attachment material covers the first portion and the second portion of the substrate edge terminal and overlaps the ledge.

16. The electronic device of claim 12, wherein:
the first portion of the substrate edge terminal defines an outward facing flank surface.

17. The electronic device of claim 12, wherein:
the second conductive layer comprises a seed layer and a plated material.

18. A method of manufacturing an electronic device, comprising:
providing an electronic component comprising:
an upper side;
a lower side opposite to the upper side;
a lateral side connecting the upper side to the lower side; and
component interconnects adjacent to the upper side;
providing an encapsulant comprising:
an encapsulant top side;
an encapsulant lower side; and
an encapsulant lateral side, wherein:
the upper side of the electronic component is exposed from the encapsulant top side; and
the encapsulant lateral side covers the lateral side of the electronic component; and
providing a substrate comprising:
a dielectric structure comprising:
a first dielectric layer; and
a second dielectric layer over the first dielectric layer and comprising a lateral end interposed between the lateral side of the electronic component and the encapsulant lateral side; and
a conductive structure comprising:
a first conductive layer coupled to the component interconnects; and
a second conductive layer coupled to the first conductive layer;
wherein:
the second conductive layer comprises a substrate edge terminal comprising a first portion that extends to overlap the lateral end of the second dielectric layer and covers a part of the first dielectric layer; and
the first portion defines an outward facing flank surface.

19. The method of claim 18, wherein:
providing the encapsulant comprises providing a tapered edge that extends from the encapsulant top side to the encapsulant lateral side; and
providing the substrate comprises providing the substrate edge terminal comprising a second portion that extends to cover a portion of the tapered edge.

20. The method of claim 18, further comprising:
providing an assembly board comprising a conductive trace; and
attaching the substrate edge terminal to the conductive trace with an attachment material, wherein:
the attachment material covers the first portion of the substrate edge terminal.
